(19) United States
(12) Patent Application Publication
(10) Pub. No.: US 2019/0002657 A1
(43) Pub. Date: Jan. 3, 2019

(54) PROCESS FOR REDUCING DEFECTS IN AN ORDERED FILM OF BLOCK COPOLYMERS

(71) Applicant: ARKEMA FRANCE, Colombes (FR)

(72) Inventors: Christophe NAVARRO, Bayonne (FR); Celia NICOLET, Sauvagnon (FR); Xavier CHEVALIER, Grenoble (FR)

(73) Assignee: ARKEMA FRANCE, Colombes (FR)

(21) Appl. No.: 16/062,491

(22) PCT Filed: Dec. 16, 2016
(86) PCT No.: PCT/EP2016/081397

§ 371 Date: Jun. 14, 2018

(30) Foreign Application Priority Data
Dec. 18, 2015 (FR) 1562786

(51) Int. Cl. C08J 5/18; C08K 5/5353; C08F 297/02; C08F 220/18; C08F 212/08; G03F 7/00; G03F 9/00

(52) U.S. Cl. CPC C08J 5/18; C08K 5/5353; C08F 297/02; C08F 2438/02; C08F 212/08; G03F 7/0002; G03F 9/7023; C08F 220/18

(57) ABSTRACT

Provided is a process for reducing the number of defects of an ordered film of a diblock copolymer on a surface. The process includes curing, on a surface, a composition including a diblock copolymer at a structuring temperature between the Tg of the diblock copolymer and the decomposition temperature of the diblock copolymer to form an ordered film of the diblock copolymer on the substrate. The composition has a product Xeffective*N of between 10.5 and 40 at the structuring temperature, where Xeffective is the Flory-Huggins parameter of the diblock copolymer and N is the total degree of polymerization of the blocks of the diblock copolymer.

The present invention relates to a process for reducing the number of defects in an ordered film of a composition comprising a block copolymer (BCP) deposited on a surface without degradation of the other critical structuring parameters (kinetics, thickness, critical dimension uniformity), this being whatever the orientation of the nanodomains (perpendicular to the substrate, parallel to the substrate, etc.); this composition having a product Xeffective*N (with X effective=Flory-Huggins parameter between the blocks under consideration, and N the total degree of polymerization of these blocks) of between 10.5 and 40, limits included, at the structuring temperature of the composition. N can be linked to the molecular weight at the peak Mp of a block copolymer measured by GPC (Gel Permeation Chromatography) by the following relationship: N=Mp/m, where m is the molar mass of the monomer and for several monomers: m=Σ(fᵢ*mᵢ), with fᵢ=mass fraction of the constituent “i” and mᵢ its molar mass.

The invention also relates to the ordered films thus obtained that can be used in particular as masks in the lithography field and also to the masks obtained.

The use of block copolymers to generate lithography masks is now well known. While this technology is promising, it may only be accepted if the levels of defects resulting from the self-organization process are sufficiently low and compatible with the standards established by the ITRS (http://www.itrs.net/). As a result, it thus appears to be necessary to have available block copolymers, the structuring process of which generates the fewest possible defects in a given time in order to facilitate the industrialization of these polymers in applications such as those of microelectronics.

The nanostructuring of a block copolymer of a surface treated by the process of the invention can take the forms such as cylindrical (hexagonal symmetry (primitive hexagonal lattice symmetry “6 mm”) according to the Hermann-Mauguin notation, or tetragonal symmetry (primitive tetragonal lattice symmetry “4 mm”)), spherical (hexagonal symmetry (primitive hexagonal lattice symmetry “6 mm” or “6/mmm”), or tetragonal symmetry (primitive tetragonal lattice symmetry “4 mm”), or cubic symmetry (lattice symmetry “mm”)), lamellar or gyroidal. Preferably, the preferred form which the nanostructuring takes is of the hexagonal cylindrical type.

The process for the structuring of block copolymers on a surface treated according to the invention is governed by thermodynamic laws. When the structuring results in a morphology of cylindrical type, each cylinder is surrounded by 6 equidistant neighbouring cylinders if there is no defect. Several types of defects can thus be identified. The first type is based on the evaluation of the number of neighbours around a cylinder which constitutes the arrangement of the block copolymer, also known as coordination number defects. If five or seven cylinders surround the cylinder under consideration, a coordination number defect will be regarded as being present. The second type of defect considers the mean distance between the cylinders surrounding the cylinder under consideration [W. Li, F. Qiu, Y. Yang and A. C. Shi, Macromolecules, 43, 2644 (2010); K. Aissou, T. Baron, M. Kogelschatz and A. Pascale, Macromol., 40, 5054 (2007); R. A. Segalman, H. Yokoyama and E. J. Kramer, Adv. Matter. 13, 1152 (2003); R. A. Segalman, H. Yokoyama and E. J. Kramer, Adv. Matter. 13, 1152 (2003)]. When this mean distance between two neighbours is greater than two % of the mean distance between two neighbours, a defect will be regarded as being present. In order to determine these two types of defects, use is conventionally made of the associated Voronoi constructions and Delaunay triangulations. After binarization of the image, the centre of each cylinder is identified. The Delaunay triangulation subsequently makes it possible to identify the number of first-order neighbours and to calculate the mean distance between two neighbours. It is thus possible to determine the number of defects.

This counting method is described in the article by X. Chevalier, C. Navarro et al. (J. Vac. Sci. Technol. B 29(6), 1071-1023, 2011).

A final type of defect relates to the angle of cylinders of the block copolymer which is deposited on the surface. When the block copolymer is no longer perpendicular to the surface but lying down parallel to the latter, a defect of orientation will be regarded as having appeared.

Pure block copolymers (BCPs) which structure themselves into ordered films and which exhibit few defects are difficult to obtain when these BCPs have high molecular weights or high values for parameters of interaction between the blocks (Flory-Huggins parameter (X)).

The applicant has noted that, within a range of the product Xeffective*N of between 10.5 and 40, preferably between 15 and 30 and even more preferably between 17 and 25, at the structuring temperature, and characterizing the composition comprising at least one block copolymer, it is possible to obtain films exhibiting a reduction in the number of defects without degradation of the other structuring characteristics (kinetics, thickness, critical dimension uniformity) compared with a composition of which the Xeffective*N is greater than 40 (below 10.5 there is no structuring).

In addition to the advantages described above, the process of the invention also makes it possible to advantageously reduce interface roughness defects. Indeed, for example but non-exhaustively, in the case of lamellar morphology, a rough interface (denoted LER for “line edge roughness”) can be observed when the structuring is not absolutely completed (which would require, for example, exceeding the time assigned for an industrial process, using annealing for a longer time) for the compositions not included in the invention. This roughness can also be observed if the desired film thicknesses are too large for given compositions, or else for example in the case of thermal annealing if the temperature required to establish the structuring is too high with respect to the heat stability of the composition. The invention makes it possible to overcome this problem given that the compositions described by the invention very rapidly complete their structuring, for large film thicknesses, with few or no defects, and for annealing temperatures that are lower than those required for block copolymers of equivalent dimensions not described by the invention.

### SUMMARY OF THE INVENTION

The invention relates to a process which makes it possible to reduce defects of an ordered film of a composition comprising at least one block copolymer on a surface, and which comprises the following steps:

mixing a composition comprising a block copolymer in a solvent, this composition exhibiting a product Xeffective*N of between 10.5 and 40 at the structuring temperature;
depositing this mixture on a surface, which is optionally pre-modified, whether it is organic or inorganic;
curing the mixture deposited on the surface at a temperature between the highest Tg (glass transition temperature) of the block copolymer(s) and their decomposition temperature such that the composition can structure itself after evaporation of the solvent without degrading.

### DETAILED DESCRIPTION

As regards the composition used in the process in accordance with the invention, any block copolymer, or blend of block copolymers, may be used in the context of the invention, provided that the product Xeffective*N of the composition comprising a block copolymer is between 10.5 and 40, preferably between 15 and 30, and even more preferably between 17 and 25 at the structuring temperature of this composition.

The Xeffective can be calculated by means of the equations of Brinke et al., Macromolecules, 1983, 16, 1827-1832. N is the total number of monomeric entities of the block copolymer.

According to a first preference, the composition comprises a triblock copolymer or a blend of triblock copolymers. According to a second preference, the composition comprises a diblock copolymer or a blend of diblock copolymers. Each block of the triblock or diblock copolymers of the composition may contain between 1 and 3 monomers, which will make it possible to finely adjust the Xeffective*N between 10.5 and 40.

The copolymers used in the composition have a molecular weight at the peak measured by SEC (Size Exclusion Chromatography) of between 100 and 500 000 g/mol and a dispersity of between 1 and 2.5, limits included, and preferably of between 1.05 and 2, limits included.

The block copolymers can be synthesized by any technique known to those skilled in the art, among which may be mentioned polycondensation, ring opening polymerization or anionic, cationic or radical polymerization. When the copolymers are prepared by radical polymerization, the latter can be controlled by any known technique, such as NMP (“Nitroxide Mediated Polymerization”), RAFT (“Reversible Addition and Fragmentation Transfer”), ATRP (“Atom Transfer Radical Polymerization”), INIFERTER (“Initiator-Transfer-Termination”), RITP (“Reverse Iodine Transfer Polymerization”) or ITP (“Iodine Transfer Polymerization”).

According to a preferred form of the invention, the block copolymers are prepared by nitroxide-mediated polymerization.

More particularly, the nitroxides resulting from the alkoxyamines derived from the stable free radical (1) are preferred.

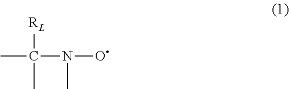

in which the radical R_{L} exhibits a molar mass of greater than 15.0342 g/mol. The radical R_{L} may be a halogen atom such as chlorine, bromine or iodine, a saturated or unsaturated, linear, branched or cyclic, hydrocarbon-based group, such as an alkyl or phenyl radical, or an ester group —COOR or an alkoxyl group —OR or a phosphonate group —PO(OR)₂, as long as it has a molar mass greater than 15.0342. The radical R_{L}, which is monovalent, is said to be in the β position with respect to the nitrogen atom of the nitroxide radical. The remaining valencies of the carbon atom and of the nitrogen atom in the formula (1) can be bonded to various radicals, such as a hydrogen atom or a hydrocarbon radical, for instance an alkyl, aryl or arylalkyl radical, comprising from 1 to 10 carbon atoms. It is not out of the question for the carbon atom and the nitrogen atom in the formula (1) to be connected to one another via a divalent radical, so as to form a ring. Preferably however, the remaining valencies of the carbon atom and of the nitrogen atom of the formula (1) are bonded to monovalent radicals. Preferably, the radical R_{L} exhibits a molar mass of greater than 30 g/mol. The radical R_{L} can, for example, have a molar mass of between 40 and 450 g/mol. By way of example, the radical R_{L} can be a radical comprising a phosphoryl group, it being possible for said radical R_{L} to be represented by the formula:

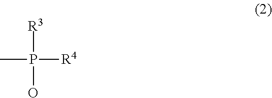

in which R³ and R⁴, which can be identical or different, can be chosen from alkyl, cycloalkyl, alkoxyl, aryloxyl, aryl, aralkyloxyl, perfluoroalkyl or aralkyl radicals and can comprise from 1 to 20 carbon atoms. R³ and/or R⁴ can also be a halogen atom, such as a chlorine or bromine or fluorine or iodine atom. The radical R_{L} can also comprise at least one aromatic ring, such as for the phenyl radical or the naphthyl radical, it being possible for the latter to be substituted, for example with an alkyl radical comprising from 1 to 4 carbon atoms.

More particularly, the alkoxyamines derived from the following stable radicals are preferred:

N-(tert-butyl)-1-phenyl-2-methylpropyl nitroxide,
N-(tert-butyl)-1-(2-naphthyl)-2-methylpropyl nitroxide,
N-(tert-butyl)-1-diethylphosphono-2,2-dimethyl propyl nitroxide,
N-(tert-butyl)-1-dibenzylphosphono-2,2-dimethylpropyl nitroxide,
N-phenyl-1-diethylphosphono-2,2-dimethylpropyl nitroxide,
N-phenyl-1-diethylphosphono-1-methylethyl nitroxide,
N-(1-phenyl-2-methylpropyl)-1-diethylphosphono-1-methylethyl nitroxide,
4-oxo-2,2,6,6-tetramethyl-1-piperidinyloxy,
2,4,6-tri(tert-butyl)phenoxy.

The alkoxyamines used in controlled radical polymerization must allow good control of the linking of the monomers. Thus, they do not all allow good control of certain monomers. For example, the alkoxyamines derived from TEMPO make it possible to control only a limited number of monomers; the same is true for the alkoxyamines derived from 2,2,5-trimethyl-4-phenyl-3-azahexane-3-nitroxide (TIPNO). On the other hand, other alkoxyamines derived from nitroxides corresponding to formula (1), particularly those derived from nitroxides corresponding to formula (2) and even more particularly those derived from N-(tert-butyl)-1-diethylphosphono-2,2-dimethyl propyl nitroxide, make it possible to broaden the controlled radical polymerization of these monomers to a large number of monomers.

In addition, the alkoxyamine opening temperature also influences the economic factor. The use of low temperatures will be preferred in order to minimize industrial difficulties. The alkoxyamines derived from nitroxides corresponding to formula (1), particularly those derived from nitroxides corresponding to formula (2) and even more particularly those derived from N-(tert-butyl)-1-diethylphosphono-2,2-dimethyl propyl nitroxide, will therefore be preferred to those derived from TEMPO or 2,2,5-trimethyl-4-phenyl-3-azahexane-3-nitroxide (TIPNO).

According to a second preferred form of the invention, the block copolymers are prepared by anionic polymerization.

When the polymerization is carried out in controlled radical fashion, the constituent monomers of the block copolymers will be chosen from vinyl, vinylidene, diene, olefinic, allyl or (meth)acrylic monomers. This monomer is more particularly chosen from vinylaromatic monomers, such as styrene or substituted styrenes, in particular α-methylstyrene, silylated styrenes, acrylic monomers, such as acrylic acid or its salts, alkyl, cycloalkyl or aryl acrylates, such as methyl, ethyl, butyl, ethylhexyl or phenyl acrylate, hydroxyalkyl acrylates, such as 2-hydroxyethyl acrylate, ether alkyl acrylates, such as 2-methoxyethyl acrylate, alkoxy- or aryloxypolyalkylene glycol acrylates, such as methoxypolyethylene glycol acrylates, ethoxypolyethylene glycol acrylates, methoxypolypropylene glycol acrylates, methoxypolyethylene glycol-polypropylene glycol acrylates or mixtures thereof, aminoalkyl acrylates, such as 2-(dimethylamino)ethyl acrylate (ADAME), fluoroacrylates, silylated acrylates, phosphorus-comprising acrylates, such as alkylene glycol acrylate phosphates, glycidyl acrylate or dicyclopentenyloxyethyl acrylate, methacrylic monomers, such as methacrylic acid or its salts, alkyl, cycloalkyl, alkenyl or aryl methacrylates, such as methyl (MMA), lauryl, cyclohexyl, allyl, phenyl or naphthyl methacrylate, hydroxyalkyl methacrylates, such as 2-hydroxyethyl methacrylate or 2-hydroxypropyl methacrylate, ether alkyl methacrylates, such as 2-ethoxyethyl methacrylate, alkoxy- or aryloxypolyalkylene glycol methacrylates, such as methoxypolyethylene glycol methacrylates, ethoxypolyethylene glycol methacrylates, methoxypolypropylene glycol methacrylates, methoxypolyethylene glycol-polypropylene glycol methacrylates or mixtures thereof, aminoalkyl methacrylates, such as 2-(dimethylamino)ethyl methacrylate (MADAME), fluoromethacrylates, such as 2,2,2-trifluoroethyl methacrylate, silylated methacrylates, such as 3-methacryloyloxypropyltrimethylsilane, phosphorus-comprising methacrylates, such as alkylene glycol methacrylate phosphates, hydroxyethylimidazolidone methacrylate, hydroxyethylimidazolidinone methacrylate or 2-(2-oxo-1-imidazolidinyl)ethyl methacrylate, acrylonitrile, acrylamide or substituted acrylamides, 4-acryloylmorpholine, N-methylolacrylamide, methacrylamide or substituted methacrylamides, N-methylolmethacrylamide, methacrylamidopropyltrimethylammonium chloride (MAPTAC), glycidyl methacrylate, dicyclopentenyloxyethyl methacrylate, itaconic acid, maleic acid or its salts, maleic anhydride, alkyl or alkoxy- or aryloxypolyalkylene glycol maleates or hemimaleates, vinylpyridine, vinylpyrrolidinone, (alkoxy)poly(alkylene glycol) vinyl ethers or divinyl ethers, such as methoxypoly(ethylene glycol) vinyl ether or poly(ethylene glycol) divinyl ether, olefinic monomers, among which may be mentioned ethylene, butene, hexene and 1-octene, 1,1-diphenylethylene, diene monomers, including butadiene or isoprene, as well as fluoroolefinic monomers and vinylidene monomers, among which may be mentioned vinylidene fluoride, alone or as a mixture of at least two abovementioned monomers.

Indeed, while wishing to maintain a value of the product Xeffective*N in the range of between 10.5 and 40, preferably between 15 and 30 and even more preferably between 17 and 25, it is sometimes necessary to use several monomers, typically 2 or 3, in one or more blocks when particular periods are targeted.

The term “period” is intended to mean the mean minimum distance separating two neighbouring domains having the same chemical composition, separated by a domain having a different chemical composition.

Typically, in the case of a diblock copolymer prepared by controlled or non-controlled radical polymerization, which is a preference in the context of the process that is the subject of the invention, it will be possible for example to consider a structure A-b-(B-co-C) wherein the block A consists of a single monomer A and the block B/C itself consists of two monomers B and C, C possibly being A. In the latter case, the structure of the diblock copolymer will be expressed A-b-(B-co-A).

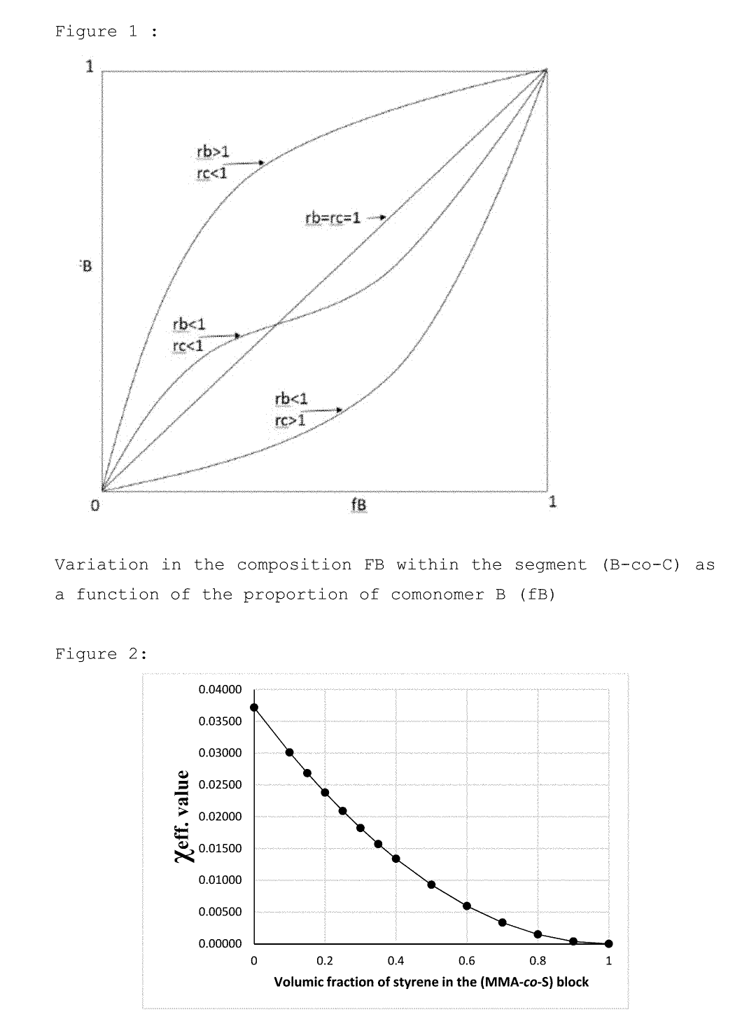

In considering the reactivity ratios rb and rc respectively of the monomers B and C (C possibly being A), it will be possible to distinguish several configurations corresponding to particular advantages when the polymerization is carried out batchwise, that is to say that the monomers B and C are introduced entirely at the beginning of the polymerization of the (B-co-C) block. These configurations are known from the literature, see for example the book by Gnanou and Fontanille, Organic and physical chemistry of polymers, Wiley, ISBN 978-0-471-72543-5. The composition diagram of page 298 of this book is reproduced in FIG. 1.

According to a first preference, rb will be greater than 1 and rc less than 1. This will result in a block (B-co-C), the composition of which will be a gradient beginning with a composition rich in monomer B and low in monomer C and finishing with a composition rich in C and low in B.

According to a second preference, rb will be between 0.95 and 1.05 and rc will be between 0.95 and 1.05. This will result in a block (B-co-C), the composition of which will be random.

According to a third preference, rb will be less than 1 and rc less than 1. This will result in a block (B-co-C), the composition of which will have a marked tendency towards the alternating of the monomers B and C.

According to a fourth preference, rb will be less than 1 and rc greater than 1. This will result in a block (B-co-C), the composition of which will be a gradient beginning with a composition rich in monomer C and low in monomer B and finishing with a composition rich in B and low in C.

According to a fifth preference and depending on the type of monomers B and C used, to counteract the effects relating to the reactivity ratios, it will be possible to carry out a continuous injection of both or of one of the two monomers B and C. This makes it possible either to dispense with the composition drift related to the reactivity ratios or to force this composition drift.

According to a sixth preference, a combination of preferences one to four with the preference five may be used, that is to say that a portion of the block (B-co-C) may be prepared in a first step according to preference one to four, and another portion may be prepared in a second step according to the same preference one to four or preference five.

According to a seventh preference, the synthesis of the (B-co-C) block will be carried out in two steps corresponding to two feedstocks of monomers B and C, optionally of equivalent composition, the second feedstock being added to the reaction mixture once the first feedstock has been converted or partially converted, the monomers not converted in the first step being removed before the introduction of the second feedstock, this being regardless of the values of rb and rc.

Preferably, A is a styrene compound, more particularly styrene, and B is a (meth)acrylic compound, more particularly methyl methacrylate. This preferred choice makes it possible to maintain the same chemical stability as a function of the temperature, compared with a PS-b-PMMA block copolymer and also enables the use of the same sublayers as for a PS-b-PMMA, these sublayers consisting of random styrene/methyl methacrylate copolymers.

When the polymerization is carried out by the anionic route, the monomers will be chosen, in a non-limiting manner, from the following monomers:

at least one vinyl, vinylidene, diene, olefinic, allyl or (meth)acrylic monomer. These monomers are more particularly chosen from vinylaromatic monomers, such as styrene or substituted styrenes, in particular a-methylstyrene, acrylic monomers, such as alkyl, cycloalkyl or aryl acrylates, such as methyl, ethyl, butyl, ethylhexyl or phenyl acrylate, ether alkyl acrylates, such as 2-methoxyethyl acrylate, alkoxy- or aryloxypolyalkylene glycol acrylates, such as methoxypolyethylene glycol acrylates, ethoxypolyethylene glycol acrylates, methoxypolypropylene glycol acrylates, methoxypolyethylene glycol-polypropylene glycol acrylates or mixtures thereof, aminoalkyl acrylates, such as 2-(dimethylamino)ethyl acrylate (ADAME), fluoroacrylates, silylated acrylates, phosphorus-comprising acrylates, such as alkylene glycol acrylate phosphates, glycidyl acrylate or dicyclopentenyloxyethyl acrylate, alkyl, cycloalkyl, alkenyl or aryl methacrylates, such as methyl (MMA), lauryl, cyclohexyl, allyl, phenyl or naphthyl methacrylate, ether alkyl methacrylates, such as 2-ethoxyethyl methacrylate, alkoxy- or aryloxypolyalkylene glycol methacrylates, such as methoxypolyethylene glycol methacrylates, ethoxypolyethylene glycol methacrylates, methoxypolypropylene glycol methacrylates, methoxypolyethylene glycol-polypropylene glycol methacrylates or mixtures thereof, aminoalkyl methacrylates, such as 2-(dimethylamino)ethyl methacrylate (MADAME), fluoromethacrylates, such as 2,2,2-trifluoroethyl methacrylate, silylated methacrylates, such as 3-methacryloyloxypropyltrimethylsilane, phosphorus-comprising methacrylates, such as alkylene glycol methacrylate phosphates, hydroxyethylimidazolidone methacrylate, hydroxyethylimidazolidinone methacrylate or 2-(2-oxo-1-imidazolidinyl)ethyl methacrylate, acrylonitrile, acrylamide or substituted acrylamides, 4-acryloylmorpholine, N-methylolacrylamide, methacrylamide or substituted methacrylamides, N-methylolmethacrylamide, methacrylamidopropyltrimethylammonium chloride (MAPTAC), glycidyl methacrylate, dicyclopentenyloxyethyl methacrylate, maleic anhydride, alkyl or alkoxy- or aryloxypolyalkylene glycol maleates or hemimaleates, vinylpyridine, vinylpyrrolidinone, (alkoxy)poly(alkylene glycol) vinyl ethers or divinyl ethers, such as methoxypoly(ethylene glycol) vinyl ether or poly(ethylene glycol) divinyl ether, olefinic monomers, among which may be mentioned ethylene, butene, hexene and 1-octene, 1,1-diphenylethylene, diene monomers, including butadiene or isoprene, as well as fluoroolefinic monomers and vinylidene monomers, among which may be mentioned vinylidene fluoride, alone or as a mixture.

Indeed, while wishing to maintain a value of the product Xeffective*N in the range of between 10.5 and 40, preferably between 15 and 30 and even more preferably between 17 and 25, it is sometimes necessary to use several monomers, typically two, in one or more blocks when particular periods are targeted.

The term “period” is intended to mean the mean minimum distance separating two neighbouring domains having the same chemical composition, separated by a domain having a different chemical composition.

Typically, in the case of a diblock copolymer which is a preference in the context of the process that is the subject of the invention, it will be possible for example to consider a structure A-b-(B-co-C) wherein the block A consists of a single monomer A and the block B-co-C itself consists of two monomers B and C, C possibly being A. In the latter case, the structure of the diblock copolymer will be expressed A-b-(B-co-A).

Preferably, A is a styrene compound, more particularly styrene, and B is a (meth)acrylic compound, more particularly methyl methacrylate. C is preferably a styrene derivative, and preferably styrene, an aryl (meth)acrylate or a vinylaryl derivative.

Preferably, and in order to incorporate the monomers into the (B-co-C) block as successfully as possible, the reactive species of the monomers B and C will exhibit a difference in pKa of less than or equal to 2.

This rule is described in Advance in Polymer Science, Vol. 153, Springer-Verlag 2000, p.79: The rule specifies that, for a given type of monomer, the initiator will have to have the same structure and the same reactivity as the propagating anionic species; in other words, the pKa of the conjugated acid of the anion that is propagating will have to correspond closely to the pKa of the conjugated acid of the species that is initiating. If the initiator is too reactive, side reactions between the initiator and the monomer may take place; if the initiator is not reactive enough, the initiating reaction will be slow and inefficient or may not take place.

The ordered film obtained with a composition comprising a block copolymer, this composition having a product between the Flory-Huggins chi parameter and the total degree of polymerization N, Xeffective*N, of between 10.5 and 40 will be able to contain additional compounds which are not block copolymers provided that this composition in the presence of these additional compounds has a product Xeffective*N, at the structuring temperature, typically between 10.5 and 40, preferably between 15 and 30 and even more preferably between 17 and 25. They can in particular be plasticizers, among which may be mentioned, without implied limitation, branched or linear phthalates, such as di(n-octyl), dibutyl, di(2-ethylhexyl), di(ethylhexyl), diisononyl, diisodecyl, benzyl butyl, diethyl, dicyclohexyl, dimethyl, di(linear undecyl) or di(linear tridecyl) phthalate, chlorinated paraffins, branched or linear trimellitates, in particular di(ethylhexyl) trimellitate, aliphatic esters or polymeric esters, epoxides, adipates, citrates, benzoates, fillers, among which may be mentioned inorganic fillers, such as carbon black, carbon or non-carbon nanotubes, ground or unground fibres, (light, in particular UV, and heat) stabilizing agents, dyes, photosensitive inorganic or organic pigments, such as, for example, porphyrins, photoinitiators, that is to say compounds capable of generating radicals under irradiation, polymeric or non-polymeric ionic compounds, taken alone or as a mixture.

The process of the invention allows an ordered film to be deposited on a surface such as silicon, the silicon exhibiting a native or thermal oxide layer, germanium, platinum, tungsten, gold, titanium nitrides, graphenes, BARC (Bottom Anti-Reflective Coating) or any other organic or inorganic anti-reflective layer used in lithography. Sometimes, it may be necessary to prepare the surface. Among the known possibilities, a random copolymer, the monomers of which can be identical in all or part to those used in the composition of block copolymer and/or of the compound which it is desired to deposit, is deposited on the surface. In a pioneering article, Mansky et al. (Science, Vol. 275, pages 1458-1460, 1997) give a good description of this technology, now well known to those skilled in the art. In a manner entirely similar to that described by Mansky et al., the surface may be modified with any other polymer (for example, a homopolymer of the block copolymer described in the context of this invention) or a copolymer that it will be judged appropriate to use.

The surfaces can be said to be “free” (flat and homogeneous surface, both from a topographical and from a chemical viewpoint) or can exhibit structures for guidance of the block copolymer “pattern”, whether this guidance is of the chemical guidance type (known as “guidance by chemical epitaxy”) or physical/topographical guidance type (known as “guidance by graphoepitaxy”).

In order to manufacture the ordered film, a solution of the block copolymer composition is deposited on the surface and then the solvent is evaporated according to techniques known to those skilled in the art, such as, for example, the spin coating, doctor blade, knife system or slot die system technique, but any other technique can be used, such as dry deposition, that is to say deposition without involving a predissolution.

A heat treatment or treatment by solvent vapour, a combination of the two treatments, or any other treatment known to those skilled in the art which makes it possible for the block copolymer composition to become correctly organized while becoming nanostructured, and thus to establish the ordered film, is subsequently carried out. In the preferred context of the invention, the curing is carried out thermally, for times of less than 24 h, preferably less than 1 h, and even more preferentially less than 5 minutes, at temperatures below 400° C., preferably below 300° C. and even more preferably below 270° C., but above the Tg of the copolymer(s) constituting the composition, this Tg being measured by differential scanning calorimetry (DSC).

The nanostructuring of a composition of the invention resulting in the ordered film can take the forms such as cylindrical (hexagonal symmetry (primitive hexagonal lattice symmetry “6 mm”) according to the Hermann-Mauguin notation, or tetragonal symmetry (primitive tetragonal lattice symmetry “4 mm”)), spherical (hexagonal symmetry (primitive hexagonal lattice symmetry “6 mm” or “6/mmm”), or tetragonal symmetry (primitive tetragonal lattice symmetry “4 mm”), or cubic symmetry (lattice symmetry “mm”)), lamellar or gyroidal. Preferably, the preferred forms taken by the nanostructurings are of hexagonal cylindrical or lamellar type.

This nanostructuring may exhibit an orientation parallel or perpendicular to the substrate. Preferably, the orientation will be perpendicular to the substrate.

The invention also relates to the ordered films thus obtained that can be used in particular as masks in the lithography field and also to the masks obtained.

### EXAMPLE n° 1

All the block copolymers were synthezied according to WO2015/011035.

Determination of X and X_{eff} for block copolymers (BCPs) involved in the study:

### PS-b-PMMA BCPs:

The X parameter for PS-b-PMMA system was measured experimentally in Y. Zhao & al., Macromolecules, 2008, 41 (24), pp 9948-9951, its value is given by the equation (1):

X_{SM}=0.0282+(4.46/T), (1)

where «T» is the self-assembly process temperature.
thus at 225° C. for instance, X_{SM}˜0.03715.

### PS-b-P(MMA-co-S) BCPs:

From G. ten Brinke & al., Macromolecules, 1983, 16, 1827-1832., for a diblock copolymer where only one of the block is constituted of two different comonomers, written as “A-b-(B-co-C)”, the Flory-Huggins parameter of this system, written as “X_{eff}”, can be determined by the formula (2):

X_{eff}=b²X_{BC}+b(X_{AB}−X_{AC}−X_{BC})+X_{AC} (2)

where:
«a», «b», «c», are the volumic fraction corresponding to each monomer in the block copolymer (for instance, «b» is the volumic fraction of “B” monomer)
«X_{AB}», «X_{AC}», «X_{BC}», are the respective Flory-Huggins interaction parameter between each relative monomers in the block copolymer (i.e. X_{AB} represent the interaction between the monomers A and B)

In the particular case where monomer “C” is the same than the one denoted «A» in the BCP formula, then (2) is simplified in: (3) X_{eff}=b²X_{AB}.

Since the relation (4) b=(1−c) is true, then equation (3) turns also to:

X_{ef}f=(1−c)²X_{AB} (5)

Thus in this particular case the X_{eff} parameter is a function of only the volumic fraction of the added co-monomer «C» in the modified block, in the notation «A-b-(B-co-C)» as compared to the simplest «A-b-B» one, and the initial x parameter between monomers “A” and “B”.

By analogy to the system of interest noted «PS-b-P(MMA-co-S)», the relation (5) becomes:

X_{eff}=(1−s)²X_{SM} (6)

Where «s» is the volumic fraction of styrene monomer introduced in the initial PMMA block, and X_{SM} is the classical Flory-Huggins interaction parameter between styrene and methylmethacrylate blocks.

By progressively varying the styrenic fraction in the MMA block, and combining the relations (1) and (6), the X_{eff} parameter is known for each value of the self-assembly temperature. The following table (Table 1) gathers these as-calculated values of X_{eff} for each point of interest in the styrene fraction versus self-assembly temperature matrix.

TABLE 1
Value of X_{eff} for the BCP “PS-b-P(MMA-co-S)” system, calculated for specific values
of styrene volumic fraction and self-assembly temperature.

| | | Self-assembly temperature (° C.) | | | | | | |
|---|---|---|---|---|---|---|---|---|
| | | 215 | 220 | 225 | 230 | 235 | 240 | 250 |
| Volumic | 0 | 0.03734 | 0.03725 | 0.03716 | 0.03707 | 0.03698 | 0.03689 | 0.03673 |
| fraction | 0.1 | 0.03024 | 0.03017 | 0.03010 | 0.03002 | 0.02995 | 0.02988 | 0.02975 |
| of | 0.15 | 0.02698 | 0.02691 | 0.02685 | 0.02678 | 0.02672 | 0.02666 | 0.02654 |
| styrene | 0.2 | 0.02390 | 0.02384 | 0.02378 | 0.02372 | 0.02367 | 0.02361 | 0.02351 |
| in the | 0.25 | 0.02100 | 0.02095 | 0.02090 | 0.02085 | 0.02080 | 0.02075 | 0.02066 |
| (MMA-co- | 0.3 | 0.01830 | 0.01825 | 0.01821 | 0.01816 | 0.01812 | 0.01808 | 0.01800 |
| S) block | 0.35 | 0.01578 | 0.01574 | 0.01570 | 0.01566 | 0.01562 | 0.01559 | 0.01552 |
| | 0.4 | 0.01344 | 0.01341 | 0.01338 | 0.01334 | 0.01331 | 0.01328 | 0.01322 |
| | 0.5 | 0.00933 | 0.00931 | 0.00929 | 0.00927 | 0.00924 | 0.00922 | 0.00918 |
| | 0.6 | 0.00597 | 0.00596 | 0.00594 | 0.00593 | 0.00592 | 0.00590 | 0.00588 |
| | 0.7 | 0.00336 | 0.00335 | 0.00334 | 0.00334 | 0.00333 | 0.00332 | 0.00331 |
| | 0.8 | 0.00149 | 0.00149 | 0.00149 | 0.00148 | 0.00148 | 0.00148 | 0.00147 |
| | 0.9 | 0.00037 | 0.00037 | 0.00037 | 0.00037 | 0.00037 | 0.00037 | 0.00037 |
| | 1 | 0 | 0 | 0 | 0 | 0 | 0 | 0 |

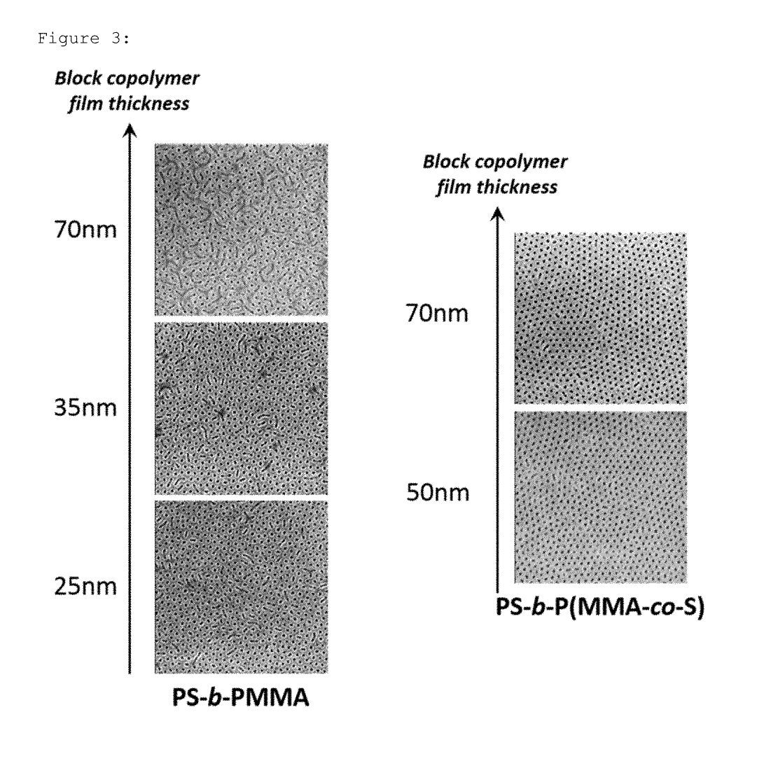

From the Table 1, the variation of the X_{eff} parameter as function of the styrene volumic fraction and for a specific temperature (225° C.) can be plotted on a graph as shown in FIG. 2, for a better understanding and representation.

FIG. 2 shows values of X_{eff} for a “PS-b-P(MMA-co-S)” system extracted from Table 1 for a particular temperature (225° C.) across the whole possible range of styrene volumic fraction.

### EXAMPLE n° 2

Extraction and calculus of X*N or X_{eff}*N values for synthesized BCPs in the context of the invention:

TABLE 2
Molecular characteristics of BCPs used in the examples (^{(a)}determined from SEM
experiment; ^{(b)}determined by SEC using standard PS; ^{(c)}determined by ¹H NMR;
^{(d)}determined from Mp; ^{(e)}extracted from Table 1).

| | BCP | | | | | % S in | | | |
|---|---|---|---|---|---|---|---|---|---|
| BCP | reference | Period | Mp | | | (MMA- | | X or X_{eff}/ | X_{eff} * N |
| architecture | n^{o} | (nm)^{(a)} | (kg/mol)^{(b)} | % PS^{(c)} | % PMMA^{(c)} | co-S)^{(c)} | N^{(d)} | temperature^{(e)} | value |
| PS-b-PMMA | A | 52 | 136 | 66 | 34 | Ø | 1325 | 0.03672 | 48.6 |
| | | | | | | | | (250° C.) | |
| PS-b-PMMA | B | 44 | 92.2 | 68.5 | 31.5 | Ø | 898 | 0.03698 | 33.2 |
| | | | | | | | | (235° C.) | |
| PS-b-P(MMA- | C | 52 | 87.2 | 78.5 | 21.5 | 25 | 845 | 0.02095 | 17.7 |
| co-S) | | | | | | | | (220° C.) | |
| PS-b-P(MMA- | D | 44 | 47.9 | 78.9 | 21.1 | 15 | 464 | 0.02691 | 12.5 |
| co-S) | | | | | | | | (220° C.) | |

For more clarity, BCPs “C” and “D” are synthesized within the invention, whereas BCPs “A” and “B” are references BCPs presenting respectively the same dimensions (see column “period”) than “C” and “D” but synthesized out of the scope of the invention (standard PS-b-PMMA BCPs taken for the direct comparison with modified ones).

This example illustrate how the invention can be used to tailor an “initial” X*N product of given BCPs (i.e. the ones of references BCPs “A” and “B”) toward a range of more appropriated values selected as regard to the associated dimension (period) of the system.

### EXAMPLE n° 3

### Realization of Typical BCP Thin Film

Underlayer powder of appropriate composition and constitution is dissolved in a good solvent, for instance propylene glycol monomethylether acetate (PGMEA), in order to get a 2% by mass solution. The solution is then coated to dryness on a cleaned substrate (i.e. silicon) with an appropriate technique (spin coating, blade coating . . . known in the state of the art) in order to get a film thickness of around 50 nm to 70 nm. The substrate is then baked under an appropriate couple of temperature and time (i.e. 200° C. during 75 seconds, or 220° C. during 10 minutes) in order to ensure the chemical grafting of the underlayer material onto the substrate; the non-grafted material is then washed away from the substrate by a rinse-step in a good solvent, and the functionalized the substrate is blown-dried under a nitrogen (or another inert gaz) stream. In the next step, the BCP solution (typically 1% or 2% by mass in PGMEA) is coated on the as-prepared substrate by spin coating (or any other technique known in the state of the art) in order to get a dry film of desired thickness (typically few tens of nanometer). The BCP film is then baked under an appropriate set of temperature and time conditions (for instance 220° C. during 5 minutes, or any of the other temperatures reported in the Table 2, or by using any other technique or combination of techniques known in the state of the art) in order to promote the self-assembly of the BCP. Optionally, the as-prepared substrate can be immersed in glacial acetic acid during few minutes, then rinsed with deionized water, and then submitted to a mild oxygen plasma during few seconds, in order to enhance the contrast of the nanometric features for SEM characterizations.

One can notice that in the following experiments and examples, the underlayer material is selected so as to be “neutral” for the studied block copolymer (i.e. so that it is able to balance the interfacial interaction between the substrate and the different blocks of the BCP material, to get a non-preferential substrate as regard to the different blocks chemistries) in order to get a perpendicular orientation of the BCP features.

In the following examples, the BCP films are characterized through SEM-imaging experiments with a CD-SEM (Critical Dimensions Scanning Electron Microscope) tool “H-9300” from Hitachi. Pictures are taken at constant magnification (appropriated for the dedicated experiment: for instance defectivity experiments are performed at magn. *100 000 to get enough statistics, whereas critical dimensions (CD) ones are performed at magn. *200 000 or magn. *300 000 to get a better precision in the dimensions) in order to allow a careful comparison of the different BCP materials.

### EXAMPLE n° 4

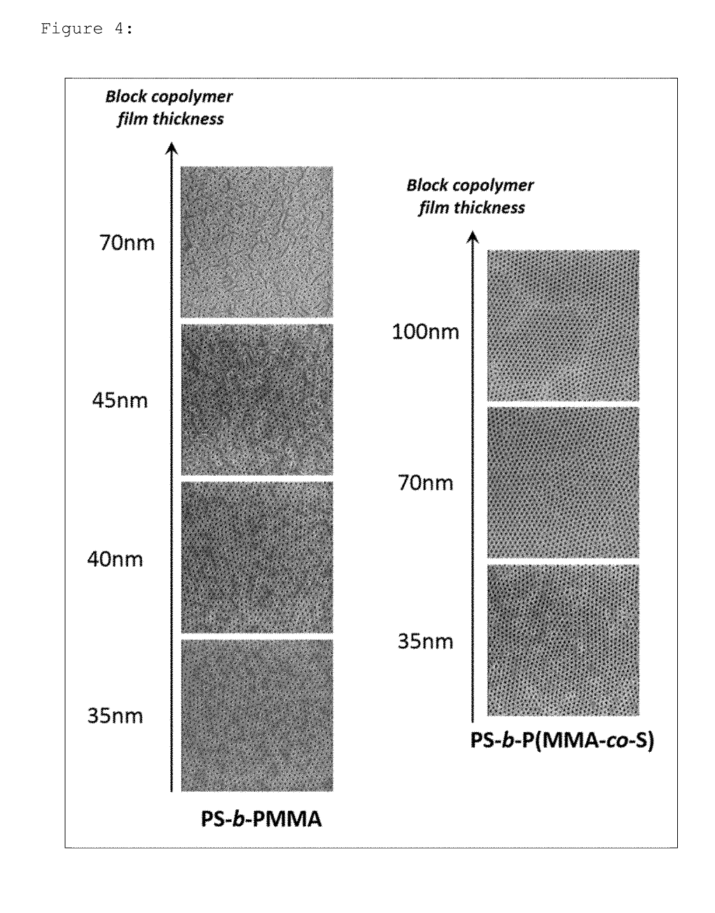

The FIG. 3 and FIG. 4 gather the raw CD-SEM results obtained for the comparison of different BCPs systems of interest, under various self-assembly conditions.

The FIG. 3 is dedicated to the comparison of the PS-b-PMMA and PS-b-P(MMA-co-S) systems of 52 nm period. The film thickness are targeted to be either the same (i.e. 70 nm) and different for the two systems, and the self-assembly temperature is chosen to be best known one for each BCP (i.e. the couple bake temperature/bake time is chosen so as to get the maximum of perpendicular cylinders for each BCP system).

The FIG. 3 is an example of raw CDSEM pictures obtained for BCP systems of ˜52 nm period, for various film thicknesses and the best self-assembly process temperature for each BCP (250° C. for PS-b-PMMA, 220° C. for PS-b-P(MMA-co-S), respectively).

The FIG. 4 is dedicated to the comparison of the PS-b-PMMA and PS-b-P(MMA-co-S) systems of 44 nm period. The comparison is performed for the same film thicknesses (i.e. 35 and 70 nm) or different ones, and for the same self-assembly process (self-assembly bake temperature 220° C. during 5 minutes) for a direct comparison of the two systems.

FIG. 4 is an example of raw CDSEM pictures obtained for BCP systems of ˜44 nm period, for various film thicknesses and a self-assembly temperature of 220° C.

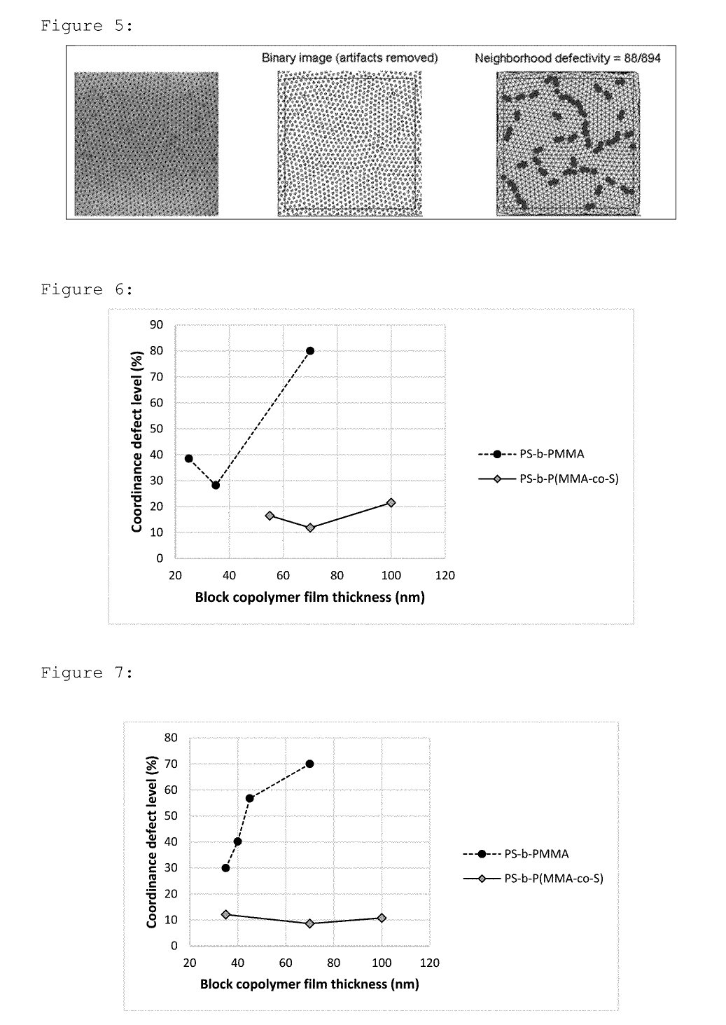

The various SEM images acquired for each BCPs under the various experimental conditions were treated with appropriate softwares already well described in the existing literature (see for instance X. Chevalier &al., Proc. SPIE 9049, Alternative Lithographic Technologies VI, 90490T (Mar. 27, 2014); doi:10.1117/12.2046329), in order to extract their corresponding coordinance defect-level of interest in the frame of the present invention. The extraction process for each picture is depicted in the FIG. 5 a reminder: FIG. 5 is an example of a SEM picture treatment to extract its defectivity level: the raw SEM image (left) is first binarized (middle) and then treated so as to detect each cylinder and its direct environment. Cylinders presenting more or less than six neighbors are counted as a defect, whereas those having exactly 6 neighbors are counted as good ones.

The CD-SEM pictures treatment results are gathered in the Table 3 below, with the corresponding associated experimental processing parameter. Each defect-level value is determined through the treatment of 10 different picture for the associated conditions, randomly chosen on the sample:

TABLE 3
Experimental parameters followed for the self-assembly of each BCP
depicted in the FIG. 3 and FIG. 4, and their respective defectivity
measurement associated (each value of defect percentage is a mean
obtained from the treatment of 10 different CDSEM pictures).

| | | | Self- | | |
|---|---|---|---|---|---|
| | | | assembly | Film | Defect |
| | BCP | Period | temperature | thickness | level |
| BCP type | reference | (nm) | (° C.) | (nm) | (%) |
| PS-b-PMMA | A | 52 | 250 | 25 | 38.5 |
| | | | | 35 | 28.2 |
| | | | | 70 | >80 |
| PS-b-P(MMA- | C | 52 | 220 | 50 | 16.5 |
| co-S) | | | | 70 | 11.8 |
| | | | | 100 | 21.5 |
| PS-b-PMMA | B | 44 | 220 | 35 | 30.0 |
| | | | | 40 | 40.2 |
| | | | | 45 | 56.7 |
| | | | | 70 | >70 |
| PS-b-P(MMA- | D | 44 | 220 | 35 | 12.1 |
| co-S) | | | | 70 | 8.6 |
| | | | | 100 | 10.8 |

The various results gathered in the Table 3, FIG. 4 and FIG. 5, allow the careful comparison of the different BCPs systems in the frame of the invention:

The FIG. 6 compares defectivity results obtained for the systems having ˜52 nm period; the film thicknesses taken at ˜70 nm for the two systems clearly indicate that the self-assembly quality is much better thanks to a lower defect level in the case of the system “PS-b-P(MMA-co-S)”, relevant for the invention, as compared to the “PS-b-PMMA” one. This is valid even if the self-assembly conditions (i.e. bake temperature) are not strictly the same.
FIG. 6 is a graphical representation of the defectivity measurements corresponding to BCPs “A” and “C” of 52 nm period reported in the Table 3. It illustrates the better quality for the self-assembly of PS-b-P(MMA-co-S) system as compared to the one of PS-b-PMMA, even for very thick films.
The FIG. 7 compares the defectivity results obtained for BCPs having a ˜44 nm period; in this case, the two different systems can be directly compared through the same film thicknesses (35 and 70nm) and self-assembly conditions (bake temperature at 220° C. during 5 minutes) experimentally used. In this case again, the measurement indicates a much better self-assembly quality for the “PS-b-P(MMA-co-S)” system relevant for the invention through a lower defectivity value as compared to the PS-b-PMMA system.
FIG. 7 is a graphical representation of the defectivity measurements corresponding to BCPs “B” and “D” of 44nm period reported in the Table 3, for the same self-assembly parameters (self-assembly bake at 220° C. during 5 minutes). It illustrates the better quality for the self-assembly of PS-b-P(MMA-co-S) system as compared to the one of PS-b-PMMA, for the same film thicknesses of thicker films.

Even if the conditions are not identical ones, the FIGS. 6 and 7 both indicate lower defectivity values the systems in the frame of the invention, independently of the film thickness used (i.e. all the defectivity values are lower for the “PS-b-P(MMA-co-S)” system than for the PS-b-PMMA one, whatever the film thickness is).

When the FIG. 6 and FIG. 7 are combined with the X*N or X_{eff}*N value for the corresponding BCP reported in the Table 2, it clearly highlights the meaningfulness of the control the X*N value for electronic applications, through the architecture and modification of the BCP under the frame of the present invention, i.e. a form «A-b-(B-co-C)» or «A-b-(B-co-A)» (like in the PS-b-P(MMA-co-S) example) for the BCP instead of the classical “A-b-B” one. In other words, the control of X*N or X_{eff}*N value through the architecture modification (like in the PS-b-P(MMA-co-S)) allows to get better defectivity values than those reported for the non-modified systems.

1-9: (canceled)

10. A process for reducing the number of defects of an ordered film of a diblock copolymer on a surface, comprising:
curing, on a surface, a composition comprising at least one diblock copolymer at a structuring temperature between the highest Tg of the at least one diblock copolymer and the decomposition temperature of the at least one diblock copolymer to form an ordered film comprising the at least one diblock copolymer on the substrate, wherein
the diblock copolymer has a structure A-b-(B-co-C), wherein
A represents a block consisting of monomer A,
B-co-C represents a block consisting of monomer B and monomer C, and
monomer C may optionally be the same as monomer A; and
the composition has a product Xeffective*N of between 10.5 and 40 at the structuring temperature, wherein
Xeffective is the Flory-Huggins parameter of the at least one diblock copolymer, and
N is the total degree of polymerization of the blocks of the at least one diblock copolymer.

11. The process of claim 10, further comprising, prior to the curing:
depositing a mixture comprising the at least one diblock copolymer and a solvent on the substrate.

12. The process of claim 11, further comprising, subsequent to the depositing and prior to the curing:
evaporating the solvent.

13. The process of claim 10, wherein monomer A and monomer C are styrene, and monomer B is methyl methacrylate.

14. The process of claim 10, wherein the at least one diblock copolymer is synthesized anionically.

15. The process of claim 10, wherein the at least one diblock copolymer is prepared by controlled radical polymerization.

16. The process of claim 15, wherein the at least one diblock copolymer is prepared by nitroxide-mediated radical polymerization.

17. The process of claim 16, wherein the at least one diblock copolymer is prepared by N-tert-butyl-1-diethylphosphono-2,2-dimethylpropyl nitroxide-mediated radical polymerization.

18. The process of claim 10, wherein the ordered film has an orientation that is perpendicular to the surface.

19. The process of claim 10, wherein the ordered film has hexagonal cylindrical form.

20. The process of claim 10, wherein the ordered film has lamellar type form.

21. The process of claim 10, wherein the substrate is silicon, germanium, platinum, tungsten, gold, titanium nitride, graphene, or a Bottom Anti-Reflective Coating (BARC).

22. The process of claim 10, wherein the composition has a product Xeffective*N of between 15 and 30 at the structuring temperature.

23. The process of claim 10, wherein the composition has a product Xeffective*N of between 17 and 25 at the structuring temperature.

24. The process of claim 10, wherein the at least one diblock copolymer has a molecular weight of 100 to 500,000 g/mol, as measured by size exclusion chromatography.

25. The process of claim 10, wherein the structuring temperature is less than 400° C.

26. The process of claim 10, wherein the structuring temperature is less than 300° C.

27. The process of claim 10, wherein the structuring temperature is less than 270° C.

28. An ordered film produced by the process of claim 10.

29. A mask obtained from the ordered film of claim 28.
